(19) United States
(12) Patent Application Publication
(10) Pub. No.: US 2026/0047382 A1
(43) Pub. Date: Feb. 12, 2026

(54) ELECTROSTATIC WAFER CLAMPING AND SENSING SYSTEM

(71) Applicant: Trek, Inc., Denver, CO (US)

(72) Inventor: Donald Enzinna, Lockport, NY (US)

(21) Appl. No.: 18/801,680

(22) Filed: Aug. 12, 2024

(51) Int. Cl. H01L 21/67; G01L 1/14; G01R 27/26

(52) U.S. Cl. CPC H01L 21/67259; G01L 1/144; G01R 27/2605

(57) ABSTRACT

A capacitance sensing system including an output, a power source configured to provide a voltage to the output, a pulsed source configured to provide a time-varying pulse train to the output, a filter arranged between the pulsed source and the output, and a sensing circuit arranged between the filter and the output. The sensing circuit can be configured to measure a voltage between the filter and the output, and based on the voltage, determine an unknown capacitance that the output is coupled to, such as that of an electrostatic chuck. This capacitance is proportional to the substrate position and indicates a quality of chucking.

### BACKGROUND

### Field

The present disclosure relates generally to monitoring electrical elements, and more particularly, to monitoring capacitance.

### Background

Electrostatic chucks are widely used in various processing systems to support workpieces, such as wafers. These chucks utilize electrostatic force to hold the workpiece in place. The electrostatic chuck includes electrodes that are energized with a clamping voltage, which electrostatically clamps the workpiece to the surface of the electrostatic chuck. The electrodes in the electrostatic chuck are coupled to an electrostatic power supply and a controller. The electrostatic power supply receives a control signal from the controller and generates a clamping voltage adapted to clamp the substrate with a clamping force.

Monitoring the position of the workpiece relative to the electrostatic chuck is of utmost relevance at various stages of the workpiece processes. For instance, it is imperative to ensure that a workpiece is properly loaded onto the electrostatic chuck before applying the clamping voltage. Furthermore, it may be desirable to determine whether the workpiece is clamped or unclamped at specific times.

The position of the workpiece can be detected by monitoring the capacitance of a combination of the workpiece and the electrostatic chuck. For example, when the workpiece is properly positioned on the electrostatic chuck, the sensed capacitance may be higher than when the workpiece is not properly positioned. The varying level of current provided to the electrostatic chuck, in response to the application of an alternating current (AC) voltage, enables the capacitance of the electrostatic chuck to be monitored. Consequently, the position of the workpiece may be monitored by monitoring the current provided to the electrostatic chuck.

However, the presence of a filter (e.g., an RF filter such as a high-impedance resistor) to protect the power supply is sometimes desired and can render inoperable known capacitive sensing systems for wafer clamping as these filters largely block the high frequency and low amplitude sensing signals used to perform capacitance sensing of substrate position on the electrostatic chuck. In some cases, such filters can reduce capacitance sensing sensitivity by a factor of 2500.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some aspects, the techniques described herein relate to a system, including: an output; a power source configured to provide a DC voltage to the output; a pulsed source configured to provide a time-varying pulse train to the output; a filter arranged between the pulsed source and the output; and a sensing circuit configured to measure a time-varying voltage between the filter and the output, and based on the time-varying voltage, determine an unknown capacitance that the output is coupled to.

In some aspects, the techniques described herein relate to an apparatus, including: a power source; a first output configured for coupling to an unknown capacitance; a square wave source configured to modify a second output of the power source; a filter arranged between the square wave source and the first output; and a voltage sensing circuit configured to measure a rate of change of a voltage between the filter and the first output and convert the rate of change to an approximation of the unknown capacitance.

In some aspects, the techniques described herein relate to a non-transitory, tangible computer-readable storage medium storing instructions that, when executed by a processor, cause a system to perform operations, including: applying first power through a first filter to a first node; applying second power through a second filter to a second node, wherein an unknown capacitance and a capacitance sensing circuit are arranged in parallel to each other and between the first and second nodes; applying a time-varying signal, via the capacitance sensing circuit, through a loop including the first node, the second node, and the unknown capacitance; and detecting a current in the capacitance sensing circuit and determining the unknown capacitance therefrom.

### BRIEF DESCRIPTION OF THE DRAWINGS

FIG. 1 illustrates an exemplary electrostatic chucking system with a power supply in series with a sinusoidal source for capacitance sensing.

FIG. 2 illustrates an exemplary electrostatic chucking system with an exemplary power supply having a pulsed source in series therewith, in accordance with one or more embodiments.

FIG. 3 provides additional details of an embodiment of the voltage sensing circuit seen in FIG. 2.

FIG. 4 presents an alternative power source where the functionality of the pulsed source is combined with the power source.

FIG. 5 presents additional details of an embodiment of the voltage sensing section and is best understood when described in combination with the timing charts of FIG. 8.

FIG. 6 presents a high-level view of a chucking system including two power sources, two filters, and a capacitance sensing circuit spanning both conduction paths.

FIG. 7 provides additional details of an embodiment of the capacitance sensing circuit seen in FIG. 6.

FIG. 8 illustrates a timing chart corresponding to the voltage sensing section shown in FIG. 5.

FIG. 9 illustrates an embodiment of a method for capacitance sensing of an unknown capacitance where a filter is arranged between a power supply and the unknown capacitance.

FIG. 10 illustrates an embodiment of another method for capacitance sensing of an unknown capacitance where a filter is arranged between a power supply and the unknown capacitance.

FIG. 11 illustrates an embodiment of yet another method for capacitance sensing of an unknown capacitance where a filter is arranged between a power supply and the unknown capacitance.

FIG. 12 is an exemplary block diagram depicting physical processing related components that may be used to realize aspects described herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Disclosed herein are multiple approaches to monitoring capacitance. Although several aspects disclosed herein are separately described, they are not mutually exclusive, and instead, these aspects may be combined in multiple variations to provide improved capacitance sensing. Although the capacitance sensing techniques are described throughout this specification in the context of electrostatic chucking systems, it should be recognized that many of the capacitance-sensing approaches disclosed herein are applicable in other contexts where capacitance sensing is useful.

The system can be used in various processing systems to support workpieces, such as wafers. These systems utilize electrostatic force to hold the workpiece in place. The electrostatic chuck includes electrodes that are energized with a clamping voltage, which electrostatically clamps the workpiece to the surface of the electrostatic chuck. The electrodes in the electrostatic chuck are coupled to an electrostatic power supply and a controller. The electrostatic power supply receives a control signal from the controller and generates a clamping voltage adapted to clamp the substrate with a clamping force. Applying a low-level time-varying signal allows a current sensing circuit to identify wafer position or chucking quality by monitoring the time-varying signal. However, some applications use a filter, such as an RF filter or other high-impedance device, after the capacitance sensing signal injection, and this filter drastically attenuates the capacitance sensing signal.

To overcome these situations, a pulsed rather than sinusoidal signal is injected into the conduction path for the clamping voltage before the filter and a voltage sensing circuit monitors changes in voltage after the filter—between the filter and the unknown capacitive load. As the pulsed voltage is applied to the unknown capacitance via the filter, the current ramps up and down through the capacitance. The slope of this ramping is inversely proportional to the unknown capacitance. Thus, use of a pulsed capacitance sensing signal before the filter and a voltage sensing circuit after the filter allows one to monitor unknown capacitance of a load despite the filter.

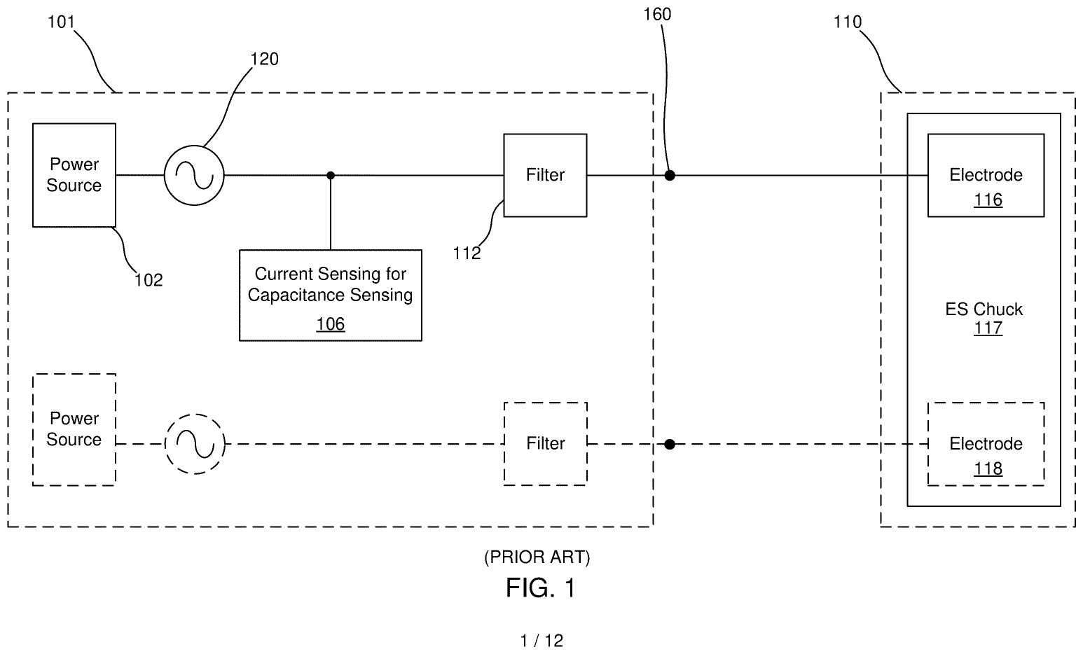

Referring first to FIG. 1, shown is a known electrostatic power supply 101 providing a chucking voltage to an electrostatic chuck 117 comprising one or more electrodes 116 and 118. The combined system can be referred to as a chucking system. As shown, the electrostatic chuck 117 is positioned within a plasma processing chamber 110.

When power is applied to the electrostatic chuck 117 via one or more conductors (e.g., cables), the workpiece to be treated (e.g., a semiconductor wafer) is electrostatically attracted to and held by the chuck 117, which supports at least in part the workpiece. A first conductor is shown coupled to electrode 116 and an optional second conductor can be coupled to electrode 118, though other monopolar and multipolar chucks have been used. As an example, six power lines and six corresponding capacitance monitors are employed in connection with a hexapolar electrostatic chuck.

In general, the electrostatic power supply 101 is capable of applying a voltage that includes steady-state and time-varying components, such as DC and AC components. For example, the DC voltage may effectuate a DC clamping voltage at the electrostatic chuck 117 that draws the workpiece to the electrostatic chuck 117 while the AC voltage may be utilized to monitor chuck capacitance, such as via a current sensing module 106 (e.g., to detect a position of the workpiece relative to the electrostatic chuck 117).

As shown, the electrostatic power supply 101 may include at least one phase, and optionally two or more phases. Each phase comprises a power source 102 typically providing a DC clamping voltage to an output 160, while a sinusoidal source 120 provides a low voltage sinusoidal signal atop the clamping voltage. A filter 112, such as a radio frequency filter, protects the power source 102, but typically also greatly attenuates the sinusoidal signal such that a current sensing module 106 is unable to approximate capacitance of an unknown capacitance at the electrostatic chuck 117. As shown, the sinusoidal source 120 and the DC power source 102 are arranged in series in a first conduction path to the output 160 (or node 160). The DC power source 102 is configured to apply a DC voltage onto the first conduction path and the sinusoidal source 120 is configured to inject a sinusoidal signal (also referred to as the capacitance sense signal) onto the first conduction path. The current sensing module 106 is coupled to the first conduction path between the sinusoidal source 120 and the filter 112 and is configured to sense a current on the first conduction path and determine an unknown capacitance of the electrostatic chuck 117 based on the current. However, the filter 112 greatly reduces the sensitivity of the current sensing module 106 to the extent that capacitance sensing can be difficult.

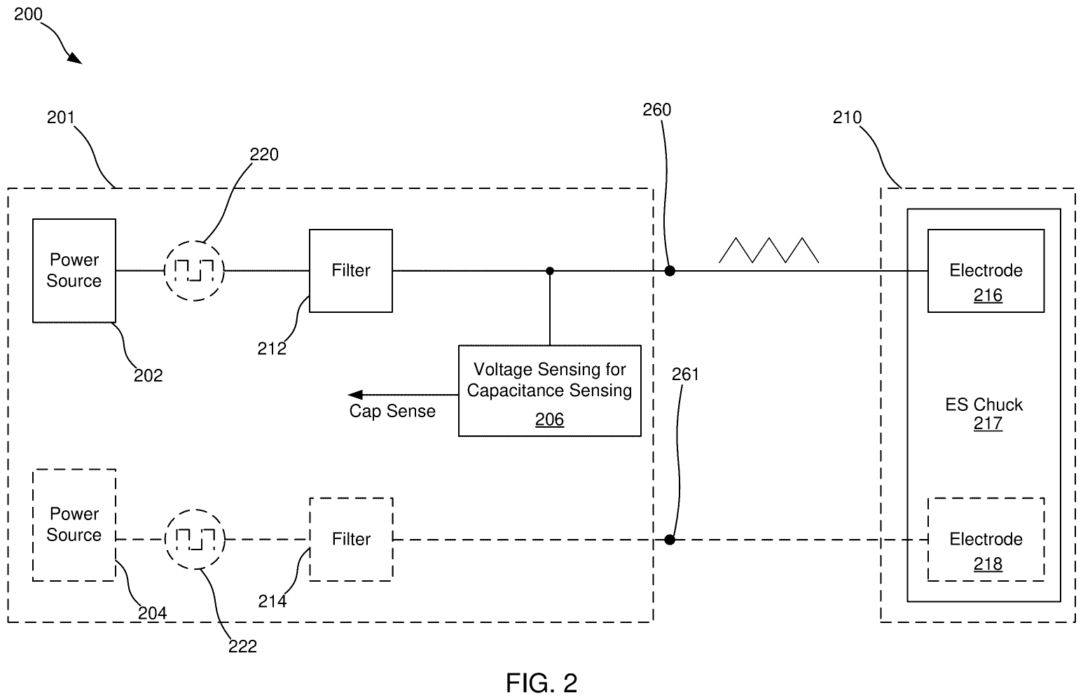

To enable capacitance sensing when this type of filter is employed between the power source and the electrostatic chuck, a voltage sensing circuit can be employed between the filter and the output (e.g., as seen in FIG. 2) and the sinusoidal source can be replaced by a pulsed source or square wave source. A power source provides a DC voltage, such as a DC clamping voltage on a first conduction path through the filter (e.g., a radio frequency filter), and a pulsed source adds a low-level time-varying component to the clamping voltage. In some cases, the functionality of the pulsed source can be embodied in a power source with the ability to provide a stepped or pulsed output. In other words, the pulse source can optionally be part of the power source. A voltage sensing circuit is arranged between, or coupled to the first conduction path between, the filter and the output. This circuit looks at voltage, and in particular, to a rate in change of voltage, or slope, and determines the unknown capacitance of the electrostatic chuck based on this rate of change in voltage. More specially, the slope is inversely proportional to the unknown capacitance. The voltage sensing circuit can then provide an indictor or control signal (“Cap Sense”) that is an estimation of the unknown capacitance that can be used by another component in the system for display, user feedback, or as part of a feedback loop (e.g., the chucking voltage from the power source may be increased to an extent if less-than-optimal chucking is occurring).

In a monopolar design, an unknown capacitance will exist between the electrode and the substrate, though other lesser capacitances associated with the electrostatic chuck may also add to the capacitance seen by the electrostatic power supply. However, where a bipolar or other monopolar design is used, current may pass through the two or more electrodes and through the substrate that the two or more electrodes are supporting. In this case, the unknown capacitance represents at least the capacitances between each electrode and the substrate. For instance, in a bipolar design, the electrostatic power supply includes a second power source, a second time-varying source, a second filter, and a second output. The electrostatic chuck can also include a corresponding second electrode.

In operation, the DC voltage applied by the DC power source may effectuate the DC clamping voltage when the electrostatic power supply is coupled to the electrostatic chuck. For example, the DC power source may be capable of applying 1000 volts DC to effect clamping, but this voltage is exemplary only and may vary depending upon many factors. In many implementations, the DC power source is realized by a switch-mode power supply, which can deliver high currents in a small form factor at high efficiency; thus, with less heat as compared to a linear amplifier. However, the disclosure is equally applicable to any type of power source, including DC sources and variable-output amplifiers to name two. The pulsed source may provide 10 to 20 volts AC (peak-to-peak) at 1 kHz, but these voltages and frequency are exemplary only and may vary depending upon many factors.

The electrostatic power supply can be used to measure an unknown capacitance of various capacitive loads, but to help with an appreciation of operation, will now be described in the context of measuring capacitance between an electrostatic chuck and a workpiece for the purpose of monitoring workpiece clamping. To detect a position of the workpiece in the context of the electrostatic power supply, the relationship between capacitance and positions of workpiece may be empirically determined, and threshold capacitances may be established that are indicative of, for example, the workpiece “in place” or the workpiece “in clamp.” The threshold capacitance values may be stored in nonvolatile memory in connection with workpiece position data to enable a mapping between capacitance values and workpiece position. The workpiece position may be determined using the empirically obtained data in connection with the rate of change in voltage measurements to obtain a capacitance seen at the electrostatic chuck. As those of ordinary skill in the art readily appreciate, capacitance of a load may be determined based upon the time-varying (e.g., AC) voltage and current as follows:

$$I ( t ) = C \frac{dV}{dt}$$

Where dv/dt is measured by the voltage sensing circuit and the current (I(t)) is a sum of currents from the power source and the pulsed source. Once the capacitance of the load (e.g., the combination of the electrostatic chuck and the workpiece) is obtained, the position of the workpiece may be obtained by reference to the stored data in nonvolatile memory.

Regardless of the specific arrangement, the system is configured to provide a high voltage clamping signal and a low frequency pulsed signal for capacitance sensing. These signals are combined, passed through a filter, and passed to a capacitive load, such as an electrostatic chuck, allowing for simultaneous clamping of the workpiece and monitoring of the clamping state. The low-level pulsed signal is able to pass largely un-attenuated through the filter and charges and discharges the unknown capacitance linearly, resulting in a triangle wave between the filter and the output. The rate of change of this triangle wave, or the slope, is inversely proportional to the unknown capacitance. Thus, unlike traditional uses of a sinusoidal low-level signal that are greatly attenuated by the filter, this solution allows capacitance sensing even where a filter is arranged between the power source and the output.

Referring to FIG. 2, the chucking system 200 includes an electrostatic power supply 201 having a power source 202 for providing a clamping voltage, a pulsed source 220 for providing a pulsed signal (or capacitance sensing signal), a filter 212, a voltage sensing circuit 206 (or capacitance sensing section 206), and an output 260 (or node 260) that is configured for coupling to a capacitive load 210 (e.g., an electrode 216 of an electrostatic chuck 217). In general, the electrostatic power supply 201 is capable of applying a voltage that includes steady-state and time-varying components, such as DC and AC components. For example, the DC voltage may effectuate a DC clamping voltage at the electrostatic chuck 217 that draws the workpiece to the electrostatic chuck 217 while the AC voltage (pulsed voltage) may be utilized to monitor chuck capacitance, such as via a voltage sensing module 206 (e.g., to detect a position of the workpiece relative to the electrostatic chuck 217).

The filter 212 is arranged to protect the power source 202, but also inhibits traditional sinusoidal capacitive sensing techniques by greatly attenuating the capacitance sensing signal, and may take the form of a radio frequency (RF) filter (e.g., a large impedance such as a 20 MΩ resistor). The capacitive load 210 includes an electrostatic chuck 217, having an electrode 216. The power source 202 may be capable of applying 1000 or 2000 volts DC, but these voltages are exemplary only and may vary depending upon many factors. In many implementations, the power source 202 is realized by a switch-mode power supply, which can deliver high currents in a small form factor at high efficiency; thus, with less heat as compared to a linear amplifier. Optionally, the electrostatic chuck 217 can be a multi-segment chuck having two or more channels and two or more corresponding electrodes.

The illustrated embodiment shows a second channel including a second power source 204, a second pulsed source 222, a second filter 214 and a second electrode 218 (or second chuck segment). In a multi-segmented configuration, the electrodes 216, 218 are configured to jointly or independently apply an electrostatic clamping force to a substrate (e.g., a semiconductor wafer) when energized with a DC voltage or current. However, one of skill in the art will appreciate that FIG. 2 is applicable to any multi-segmented electrostatic chuck, such as those having six segments or channels. The voltage sensing circuit 206 is coupled to the first channel, but not the second channel, though in some instances, a second voltage sensing circuit on the second channel can be implemented. The electrostatic chuck 217, via the one or more electrodes, generates an electrostatic force that clamps the workpiece (not shown), such as a wafer, to the surface of the electrostatic chuck 217. The clamping force is adapted to the substrate, ensuring a secure hold during various workpiece processes.

In this exemplary application, the capacitive load 210 can be a plasma processing chamber realized by chambers of substantially conventional construction (e.g., comprising a vacuum enclosure which is evacuated by a pump or pumps (not shown)). And, as one of ordinary skill in the art will appreciate, the plasma excitation in the plasma processing chamber may be achieved by any one of a variety of sources comprising, as just one example, a helicon type plasma source, which includes magnetic coil and antenna to ignite and sustain a plasma in the reactor, and a gas inlet for introduction of a gas into the plasma processing chamber.

In some cases, the power source 202 (and optionally 204) is configured to turn on and off in response to the clamping and declamping of substrates. This operational variation allows for dynamic control of the clamping force applied to the workpiece. When a substrate is to be clamped, the power source 202 is turned on, generating the high voltage clamping signal that energizes the electrode(s) 216 (and optionally 218) of the electrostatic chuck 217. Conversely, when a substrate is to be declamped, such as for moving the substrate to a next chamber in a processing line, the power source 202 (and optionally 204) is turned off, ceasing the generation of the high voltage clamping signal and allowing the workpiece to be released from the electrostatic chuck 217. This operational flexibility enhances the chucking system's 200 adaptability to different workpiece processes and conditions. The power source 202 (and optionally 204) can provide DC or AC power and some non-limiting examples include a high voltage DC power supply, DC power supply with a pulsed output, or a variable output amplifier.

The filter 212, such as a radio frequency filter for removing radio frequencies, can disturb or block known capacitance sensing signals as discussed relative to FIG. 1. Accordingly, the pulsed source 220 (and optionally 222) uses a square wave or pulsed signal that sees little attenuation by the filter 212 and allows the voltage sensing circuit 206 to monitor a rate of change in the voltage on the first conduction path between the filter 212 and the output 260. In these ways, the chucking system 200 and its voltage sensing circuit 206, can monitor the position of a workpiece via capacitance, or the capacitance of any capacitive load, even when a filter is arranged between the power source 202 and a capacitive load, such as an electrostatic chuck.

Although only one of the two illustrated channels includes a capacitance circuit 206, in other embodiments, both channels can be monitored via a separate capacitance sensing.

The pulsed source 220 is typically not isolated from the first conduction path and may be serially integrated into the conduction path either between the 202 power source and the 212 filter or as part of the power source 202.

The voltage sensing circuit 206 can be powered by an isolated power supply (not shown) and can provide the capacitive sensing signal via isolating means, such as, but not limited to, an optoisolator. RF immunity is assumed since the voltage sensing circuit 206 is floating and is differential.

In some implementations, the voltage sensing circuit 206 is implemented in a separate housing from the power source 202 of the electrostatic power supply 201. For example, a circuit for measuring capacitance of a load may be implemented without the DC power source 202, and the voltage sensing circuit 206 for measuring capacitance may not have the functionality to clamp the workpiece to the electrostatic chuck 217. To this end, throughout this disclosure a voltage sensing circuit will be described separate from the power source, though part of an electrostatic power supply. In yet other embodiments, the voltage sensing circuit 206 can be a separate modular component that can be added to existing power supplies or between existing power supplies and capacitive loads (e.g., electrostatic chucks). This configuration allows for the system to be added as a modular component to existing off-the-shelf power supplies or amplifiers. This can be particularly beneficial in scenarios where there is a desire to add capacitance sensing capabilities to existing equipment without the need for extensive modifications or custom-built components. In other cases, the system is part of the power source. This configuration allows for a more integrated solution, where the system is built directly into the power supply or amplifier. This can provide advantages in terms of space efficiency and system integration, as the system components are primarily contained within a single apparatus. This can also simplify the system design and reduce the number of external connections, potentially enhancing the reliability and robustness of the system.

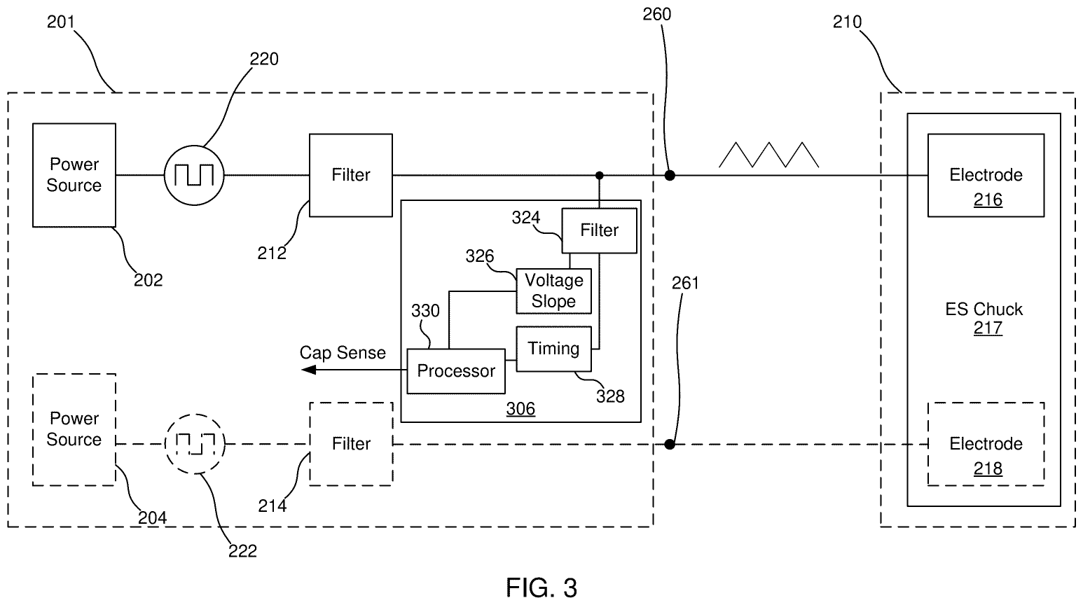

FIG. 3 provides additional details of an embodiment of the voltage sensing circuit seen in FIG. 2. The power source 202 provides a DC voltage, such as a high voltage clamping signal, and a pulsed signal is injected into this DC voltage via the pulsed source 220 to form a combined signal. The combined signal passes through the filter 212 and to the output 260 where it is configured for provision to the load 210 having an unknown capacitance, in this case, a first electrode 216 of an electrostatic chuck 217. The combination of these signals allows for simultaneous clamping of the workpiece and monitoring of the clamping state. The high voltage DC clamping signal provides the electrostatic force for clamping the workpiece, while the low frequency capacitance sensing pulsed signal from the pulsed source 220, provides a means for monitoring the clamping state based on a sensed capacitance. Changes in capacitance at the electrostatic chuck 217 will not be reflected in changes to the high voltage DC offset of the combined signal (the portion coming from the power source 202), but will be seen as ramping voltages that can be detected by the voltage sensing circuit 306.

Specifically, the voltage sensing circuit 306 monitors a voltage on the first conduction path between the filter 212 and the output 260 (i.e., monitors the combined signal). The voltage sensing circuit 306 includes a filter 324, such as an LC filter, preventing DC currents and voltages from passing between the first conduction path and the voltage sensing circuit 306. However, time-varying signals, such as the pulsed signal, pass through the filter 324 allowing the voltage sensing circuit 306 to monitor changes in voltage of the combined signal on the first conduction path, but also to be safe from high DC voltages therein. A slope module 326 measures the rate of change of the voltage as the low-level pulsed signal on the first conduction path charges and discharges the unknown capacitance. A timing module 328 assesses a time between reference levels of the slope. The outputs of these two modules are processed by a processor 330 to provide a capacitive sensing signal used to monitor substrate position or the quality of electrostatic clamping. Changes in the measured slope correspond to changes in the unknown capacitance, and more specifically, there is an inverse relationship between the slope and the unknown capacitance. Thus, increasing slope indicates decreasing capacitance, and vice versa. The capacitive sensing signal can be provided to a user interface, for instance, or used in a feedback loop (e.g., to increase the clamping voltage when chucking is less than optimal), as another non-limiting example. Various uses of the capacitive sensing signal are known in the art, and thus the specific application of this signal should not be deemed as limiting the scope and disclosure herein. The capacitive sensing signal can be provided via an isolated means, such as an opto-isolator. The filter 324 can be implemented as a common mode choke, though this is only one of numerous examples.

In some configurations, a multi-segmented electrostatic chuck is implemented, each segment having a different power source, though a single capacitance sensing system can be used. On the other hand, multiple capacitance sensing systems can be implemented. These configurations allow for precise control over the clamping force applied to different segments of the workpiece, thereby enhancing the overall performance of the electrostatic wafer clamping and sensing system. The illustrated embodiment includes a single channel, a single power source 202, a single voltage sensing circuit 306, and a single electrode 216 and filter 212. However, this embodiment is optionally shown with a second channel and a second set of corresponding components (204, 222, 214, 261), though only a single voltage sensing circuit.

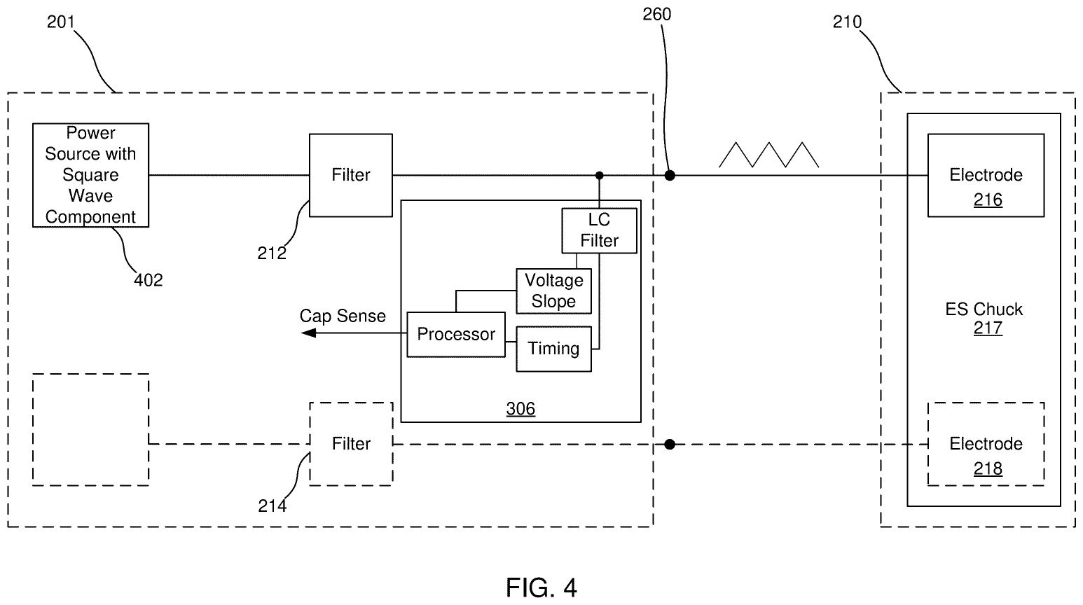

FIG. 4 presents an alternative power source 402 where the functionality of the pulsed source is combined with the power source 402. For instance, the power source 402 could be a stepped output power source 402 able to produce high voltage DC clamping voltages having a stepped output. The stepped portion is a low-level signal that affects the capacitance sensing. Alternatively, a high voltage amplifier could be implemented. Other high voltage power sources able to produce a small stepped fluctuation in voltage can also be used.

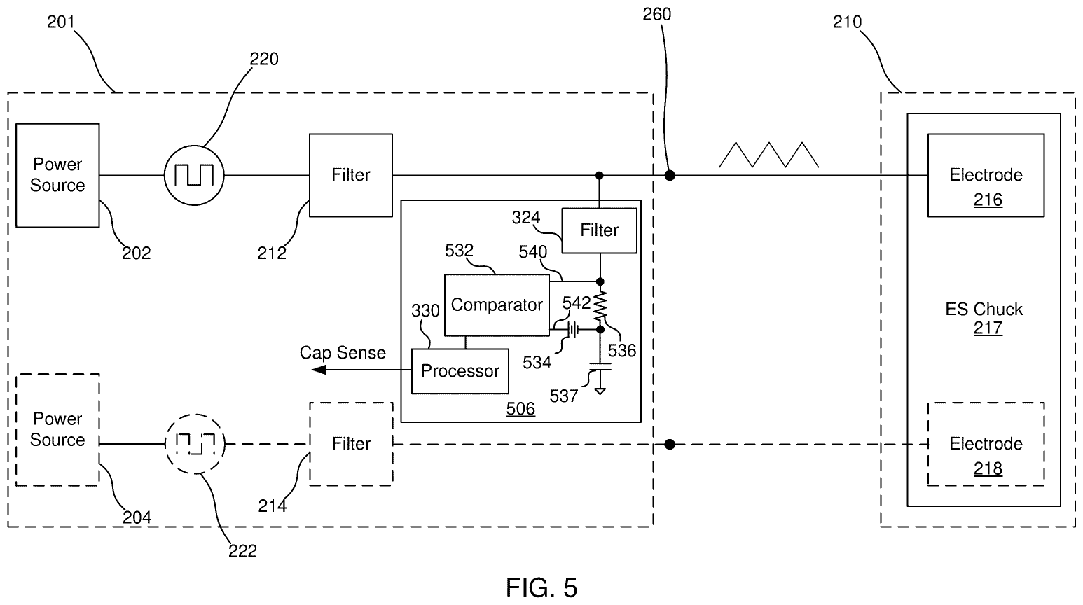

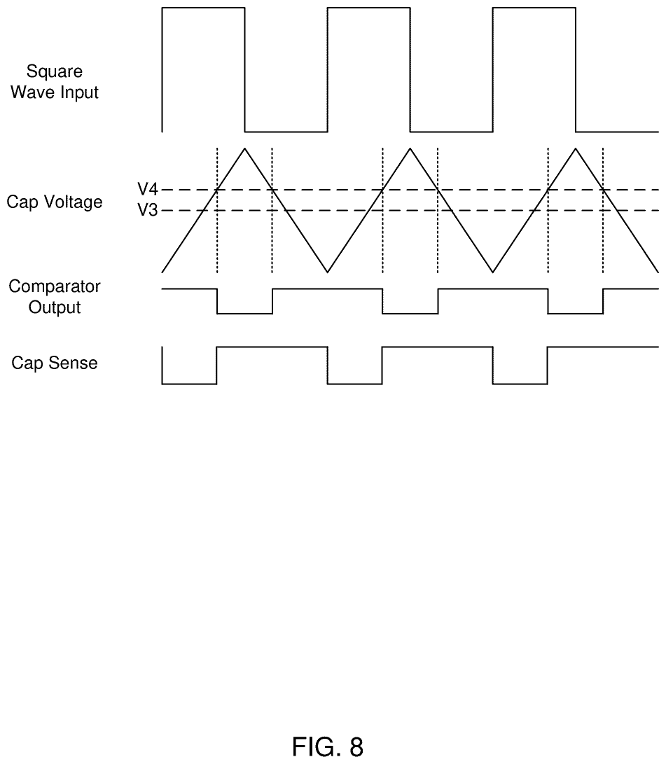

FIG. 5 presents additional details of an embodiment of the voltage sensing section and is best understood when described in combination with the timing charts of FIG. 8. The voltage sensing circuit 506 again employs a filter (e.g., an LC filter) to isolate the voltage sensing circuit 506 from DC voltages on the first conduction path, but allows sensing of changes in voltage. As the unknown capacitance linearly charges and discharges, a small current passes through an impedance 536 and a comparator 532 monitors voltages at both sides of the impedance 536. Additionally, one of the two comparator inputs is DC biased via a DC source 534. A capacitance 537 arranged between the impedance 536 and a floating ground can DC isolate the comparator 532 from ground. The DC bias allows the comparator 532 to monitor changing voltages on the first conduction path and to flip or provide an output signal when a slope of the voltage on the first conduction path passes a threshold. The processor 330 can use the output of the comparator 532 to generate a capacitance sensing signal as previously discussed relative to FIGS. 2 and 3.

Said another way, and referring to FIG. 8, the high periods of the pulsed source cause an upward linear ramping of the voltage across the unknown capacitance. As the pulses go low, the voltage across the unknown capacitance ramps down. The result is a triangle wave across the unknown capacitance and a proportional triangle wave at the first input 540 of the comparator 532. The capacitance 537 and the impedance 536 form a low-pass filter that removes the frequency of the triangle wave and effectively presents an average of the triangle wave at the second input of the comparator 532, though offset by a small DC bias (e.g., 50-100 mV) from DC source 534 that creates a threshold or trip point for the comparator 532. In FIG. 8 V3 is the average voltage formed between the impedance 536 and the capacitance 537, while V4 is the offset voltage that the second input of the comparator 532 sees. Thus, the comparator 532 compares the triangle wave at the first input 540 to the DC offset average at the second input 542 and whenever these two values intersect, the comparator 532 output switches. The comparator 532 output is low when the voltage across the unknown capacitance is greater than the threshold voltage V4 and high when the voltage across the unknown capacitance is less than the threshold voltage V4. The processor uses a logical NAND on the comparator 532 output and the square wave to produce the capacitance sensing signal. Since the slope of the voltage across the unknown capacitance is inversely proportional to the unknown capacitance, as the capacitance increases, the slope will decrease and the duty cycle of low capacitance sensing pulses will decrease. As the unknown capacitance decreases, the slope will increase and the duty cycle of the low capacitance sensing pulses will increase.

It should be noted that although the power source 202 and pulsed source 220 are shown independent from each other, as discussed earlier, the power source 202 can include the pulsed functionality of the pulsed source 220. It should be appreciated that other averaging circuits could be used to provide the second input of the comparator 532.

The ground connection below the capacitance 537 is floating and at the same potential as the output of the power source 202.

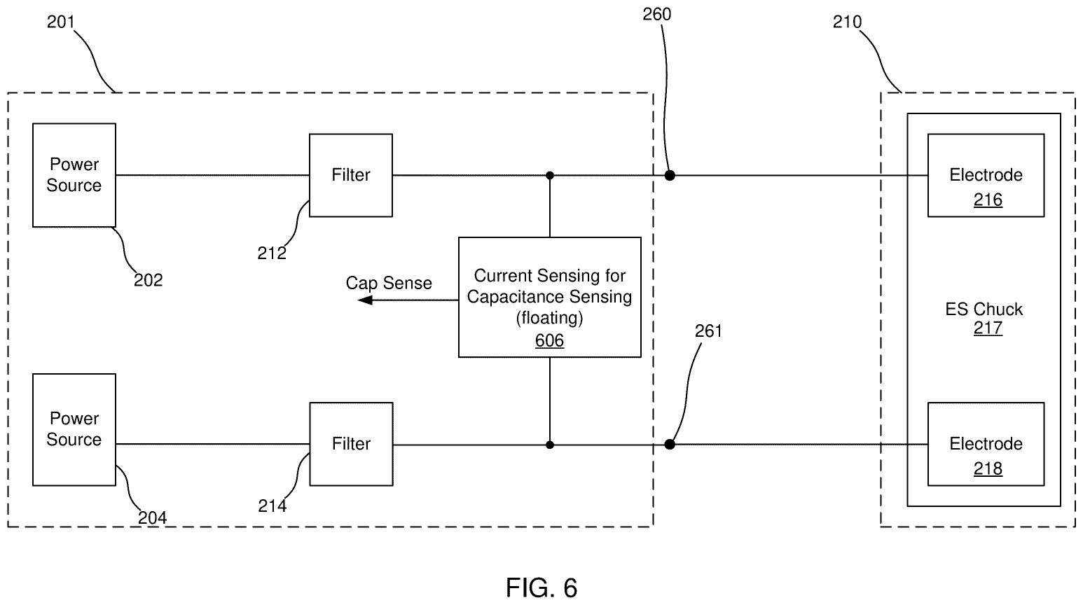

Although monitoring the slope of the voltage on one of the conduction paths as so far discussed is one way to perform capacitance sensing when a filter is in the path, and thereby to monitor chucking, capacitance sensing across two or more conduction paths or channels may also be effective. FIG. 6 presents a high-level view of a chucking system including two power sources, two filters, and a capacitance sensing circuit spanning both conduction paths downstream from the filters (i.e., between the filters and the outputs). Each channel has its own output 260 and 261 that is configured for coupling to respective electrodes 216 and 218 of an electrostatic chuck 217, optionally part of a capacitive load 210. The capacitance sensing circuit 606 is configured to inject a time-varying signal, such as a sinusoidal signal (as compared to the pulsed signal of FIGS. 2-5), onto the first and second conduction paths and thereby to form a current loop with the electrodes 216 and 218 and the substrate (or whatever forms the capacitive load 210). The capacitance sensing circuit 606 monitors the current passing therethrough as this current is proportional to the unknown capacitance. It then provides a capacitance sensing signal that can be used for a variety of purposes such as at a user interface or as part of a feedback loop. The capacitance sensing signal can be a proxy for substrate position or the quality of electrostatic chucking. The capacitance sensing signal can take the form of a pulse width modulation signal, a frequency, or serial data, to name a few non-limiting examples.

Although an electrostatic chuck 217 is shown, other capacitive loads can also be remotely probed via this method.

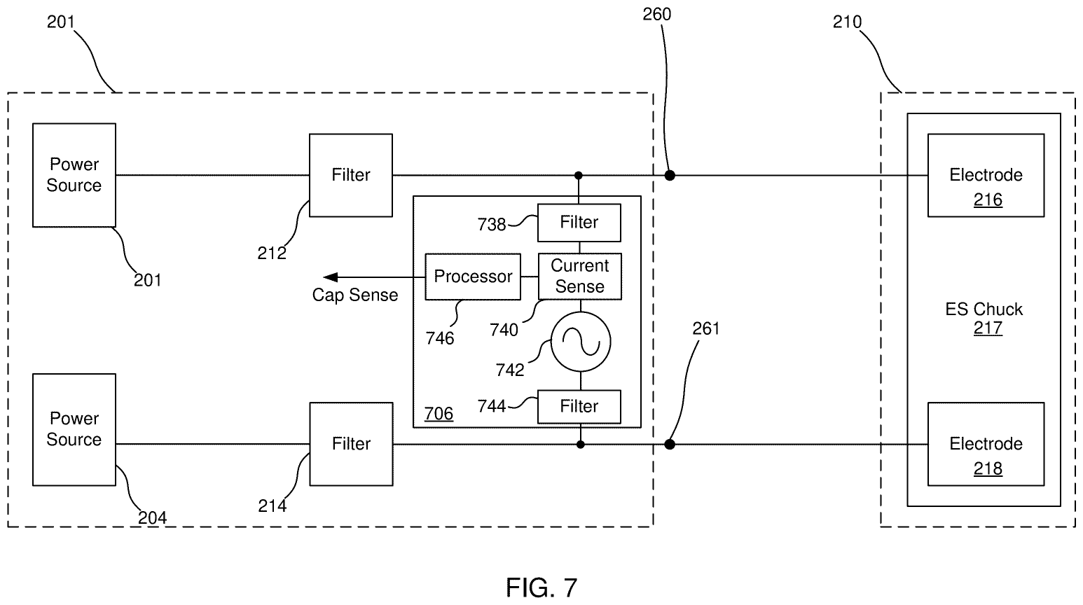

FIG. 7 provides a more detailed embodiment of the capacitance sensing circuit. The capacitance sensing circuit 706 can include filters at both ends isolating the capacitance sensing circuit 706 from DC voltages and currents on the first and second conduction paths. However, a time-varying source 742 (e.g., a sinusoidal source) arranged between these filters injects a time-varying signal onto both conduction paths through the filters 738 and 744 and forms an AC loop including the capacitance sensing circuit 706, both outputs 260 and 261, both electrodes 216 and 218, and the substrate (not shown) spanning both electrodes 216 and 218. The time-varying signal is phase shifted between the first and second outputs 260 and 261. The capacitance sensing circuit 706 can be parallel to the unknown capacitance. A current sense 740 monitors the current, which is proportional to the unknown capacitance, and the processor 746 can analyze the current and provide a capacitance sensing signal in response. The capacitance sensing signal can be routed via isolating means, such as an optocoupler, in order to maintain isolation of the capacitance sensing circuit 706. Additionally, the capacitance sensing circuit 706 is floating. The time-varying source 742 can be a voltage source such that voltage is regulated, but current adjusts according to the unknown capacitance, and this changing current is monitored by the current sense 740.

In some embodiments, the filters 738 and 744 can be LC filters. In some embodiments, the filters 212 and 214 can be large impedances such as, but not limited to, 20 MΩ resistors. The capacitance sensing circuit 706 can be powered by an isolated power supply (not shown) having an earth-referenced power in and a floating ground connection. To further maintain isolation, the capacitance sensing signal can be transmitted via one of various known isolation mechanisms such as an optoisolator.

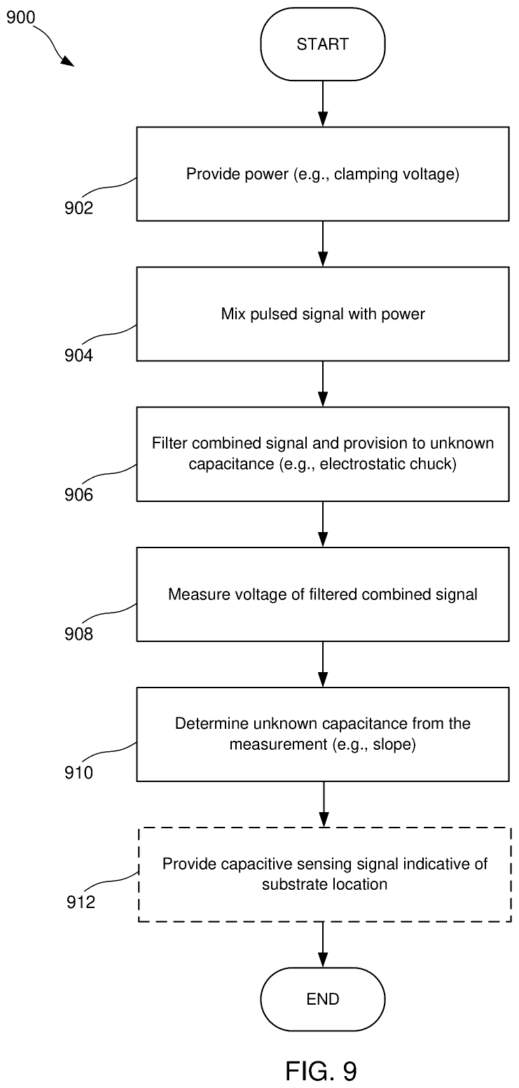

FIG. 9 illustrates an embodiment of a method for capacitance sensing of an unknown capacitance where a filter is arranged between a power supply and the unknown capacitance. The method 900 includes providing a power such as a clamping voltage (e.g., 1000-2000 V DC pulsed to effectuate clamping and declamping) (Block 902) and providing a pulsed signal (the capacitance sensing signal) and mixing it with the power (Block 904)—this pulsed signal typically having a much lower amplitude than the clamping voltage. This forms a combined signal, which is filtered and provided to the unknown capacitance or capacitive load (Block 906) such as an electrostatic chuck. The method further includes measuring the voltage of the filtered combined signal (Block 908) and determining the unknown capacitance based on the measured filtered combined signal (Block 910). Optionally, the unknown capacitance can be relayed to a user interface, used in a feedback loop, or otherwise provisioned as a capacitance sensing signal (Block 912) that in the case of an electrostatic chuck is indicative of a substrate position on the chuck or quality of chucking. Where used in a feedback loop, the capacitance sensing signal can be fed back to control of the power supply to adjust the clamping voltage.

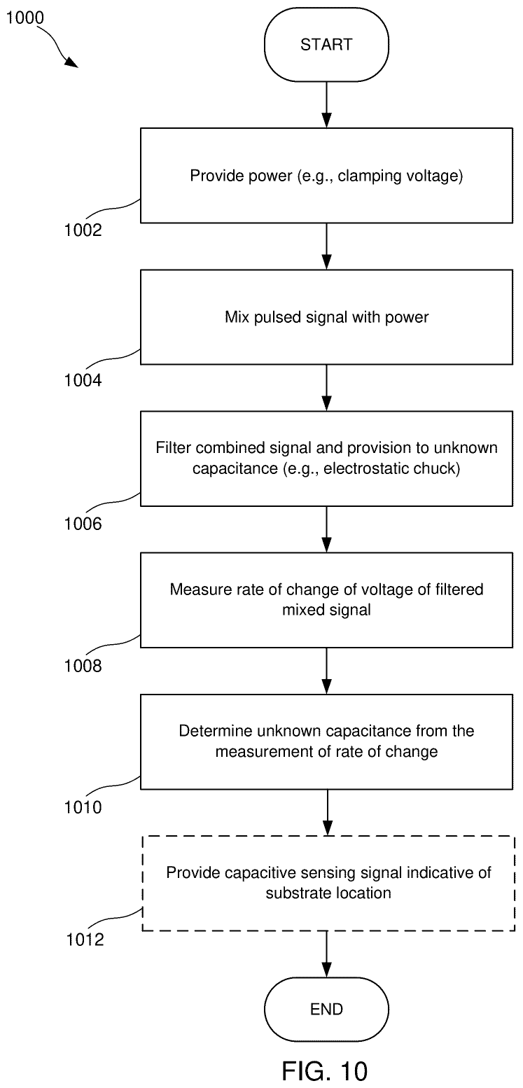

FIG. 10 illustrates an embodiment of another method for capacitance sensing of an unknown capacitance where a filter is arranged between a power supply and the unknown capacitance. The method 1000 includes providing a power such as a clamping voltage (e.g., 1000-2000 V DC pulsed to effectuate clamping and declamping) (Block 1002) and providing a pulsed signal (the capacitance sensing signal) and mixing it with the power (Block 1004)—this pulsed signal typically having a much lower amplitude than the clamping voltage. This forms a combined signal, which is filtered and provided to the unknown capacitance or capacitive load (Block 1006) such as an electrostatic chuck. The method further includes measuring the rate of change of the voltage of the filtered combined signal (Block 1008) (i.e., slope) and determining the unknown capacitance based on the measured rate of change (Block 1010). Optionally, the unknown capacitance can be relayed to a user interface, used in a feedback loop, or otherwise provisioned as a capacitance sensing signal (Block 1012) that in the case of an electrostatic chuck is indicative of a substrate position on the chuck or quality of chucking. Where used in a feedback loop, the capacitance sensing signal can be fed back to control of the power supply to adjust the clamping voltage.

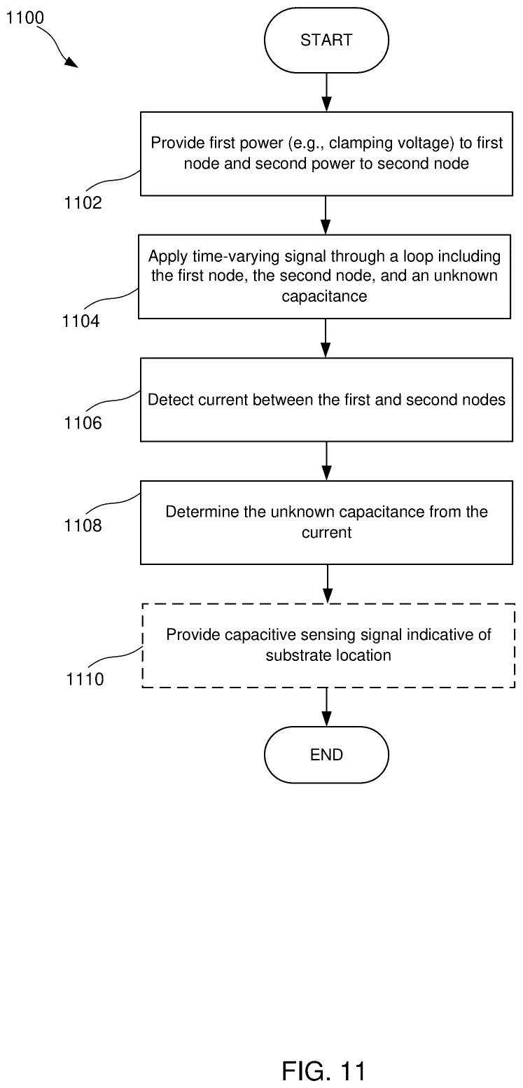

FIG. 11 illustrates an embodiment of yet another method for capacitance sensing of an unknown capacitance where a filter is arranged between a power supply and the unknown capacitance. The method 1100 includes providing first power to a first node and providing second power to a second node (Block 1102). These can be known as clamping voltages and each is provided on a separate channel or conduction path. In some instances, these nodes can be outputs of the power supply. Instead of provided a pulsed signal directly into the conduction paths as described in methods 900 and 1000, method 1100 applies a time-varying low-level signal such as a sinusoidal signal between the conduction paths and through a loop including the two nodes and an unknown capacitance or the capacitive load (Block 1104). The time-varying signal is typically much lower than the first and second power or clamping voltages. A current sensor detects the current between the two nodes, which is proportional to the unknown capacitance (Block 1106). This current can be converted to a capacitance value (Block 1108). Optionally, the unknown capacitance can be relayed to a user interface, used in a feedback loop, or otherwise provisioned as a capacitance sensing signal (Block 1110) that in the case of an electrostatic chuck is indicative of a substrate position on the chuck or quality of chucking. Where used in a feedback loop, the capacitance sensing signal can be fed back to control of the power supply to adjust the clamping voltage.

Although the herein disclosed capacitance sensing system has been described and shown primarily as applied to a plasma processing system, it also has application in other industries, such as, but not limited to, the automotive industry and aerospace. In some embodiments, the capacitance sensing system can be applied to monitoring and controlling the position of various components, especially where fine accuracy is needed, such as in controlling the position of robotic arms and cutters and 3D printing heads. As another example, it can be used in the electrostatic painting process where the position of the car body parts is of utmost relevance. The system can ensure that the parts are properly positioned before the painting process begins, thereby improving the quality of the paint job and reducing waste.

In the manufacturing industry, the capacitance sensing system can be used in automated assembly lines. The system can monitor the position of the workpieces and ensure they are correctly placed before the assembly process begins. This can help to prevent errors and improve the efficiency of the assembly line.

The capacitance sensing system can be used in the medical field for monitoring the position of medical devices or components. For example, it can be used in the positioning of a patient during a medical imaging procedure such as an MRI or CT scan. The system can ensure that the patient is properly positioned before the imaging process begins, thereby improving the quality of the images and reducing the risk of errors.

In robotics, the capacitance sensing system can be used to monitor the position of robotic arms or other components. This can help to ensure that the robotic components are properly positioned before performing a task, thereby improving the accuracy and efficiency of the robotic system.

The capacitance sensing system can be used in the production of consumer electronics such as smartphones, tablets, and laptops. The system can monitor the position of various components during the assembly process, ensuring they are correctly placed before the assembly process continues. This can help to prevent errors and improve the quality of the final product.

As shown above, the applications of the herein disclosed capacitance sensing system are myriad.

Although the capacitance sensing has been shown primarily on a single channel in these figures, in other embodiments, more than one channel could include capacitance sensing (e.g., two of two channels). Similarly, while each channel has been shown with a filter, in some embodiments, less than all channels may include a filter (e.g., one of two channels).

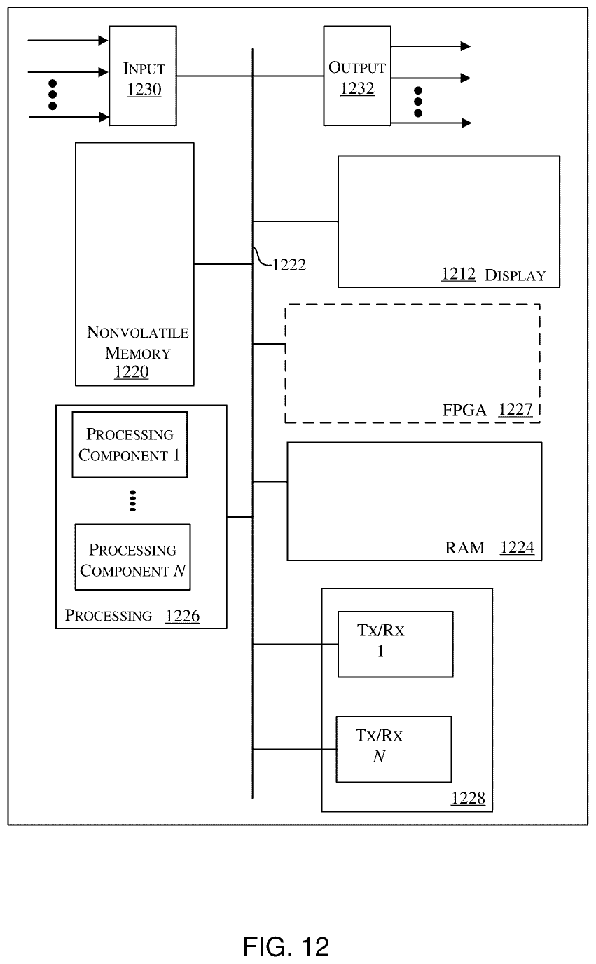

As described above, the functions and methods described in connection with the embodiments disclosed herein may be effectuated utilizing hardware, in processor executable instructions encoded in non-transitory, tangible computer-readable storage medium, or as a combination of the two. Referring to FIG. 12 for example, shown is a block diagram depicting physical components that may be utilized to realize one or more aspects of the capacitance sensing technologies disclosed herein. Moreover, multiple instances of the computing device depicted in FIG. 12 may be implemented in the systems described herein. As shown, in this embodiment a display 1212 and nonvolatile memory 1220 are coupled to a bus 1222 that is also coupled to random access memory (“RAM”) 1224, a processing portion (which includes N processing components) 1226, a field programmable gate array (FPGA) 1227, and a transceiver component 1228 that includes N transceivers. Although the components depicted in FIG. 12 represent physical components, FIG. 12 is not intended to be a detailed hardware diagram; thus, many of the components depicted in FIG. 12 may be realized by common constructs or distributed among additional physical components. Moreover, it is contemplated that other existing and yet-to-be developed physical components and architectures may be utilized to implement the functional components described with reference to FIG. 12.

The display 1212 generally operates to provide a user interface for a user, and in several implementations, the display 1212 is realized by a touchscreen display. For example, display 1212 can be implemented as a user interface for the capacitance sensing signals to enable a user to change settings of the systems disclosed herein and/or receive operational feedback about the systems comprising workpiece (e.g., substrate) position information and capacitance information.

In general, the nonvolatile memory 1220 is non-transitory memory that functions to store (e.g., persistently store) data and machine readable (e.g., processor executable) code (comprising executable code that is associated with effectuating the methods described herein). In some embodiments, for example, the nonvolatile memory 1220 includes bootloader code, operating system code, file system code, and non-transitory processor-executable code to facilitate the execution of the methods described herein. The nonvolatile memory 1220 may also be used to store empirically obtained data that relates workpiece position to capacitance data (or workpiece position to voltage slope between the filter and output).

In many implementations, the nonvolatile memory 1220 is realized by flash memory (e.g., NAND or ONENAND memory), but it is contemplated that other memory types may also be utilized. Although it may be possible to execute the code from the nonvolatile memory 1220, the executable code in the nonvolatile memory is typically loaded into RAM 1224 and executed by one or more of the N processing components in the processing portion 1226.

In operation, the N processing components in connection with RAM 1224 may generally operate to execute the instructions stored in nonvolatile memory 1220 to realize the functionality of one or more components and modules disclosed herein. As one of ordinary skill in the art will appreciate, the processing portion 1226 may include a video processor, digital signal processor (DSP), graphics processing unit (GPU), and other processing components. In digital implementations, a DSP may be used to effectuate aspects of the pulsed signal injection.

In addition, or in the alternative, the field programmable gate array (FPGA) 1227 may be configured to effectuate one or more aspects of the functions and methodologies described herein. For example, non-transitory FPGA-configuration-instructions may be persistently stored in nonvolatile memory 1220 and accessed by the FPGA 1227 (e.g., during boot up) to configure the FPGA 1227 to effectuate the functions described herein.

The input component 1230 may operate to receive signals (e.g., from the current and voltage sensors) that are indicative of the unknown capacitance. And the output component 1232 generally operates to provide one or more analog or digital signals to effectuate an operational aspect of components described herein. For example, the output portion 1232 may transmit output signal(s) indicative of voltage modulation levels corresponding to workpiece position or feedback signals to adjust the power source's clamping voltage in response to imprecise clamping situations.

The depicted transceiver component 1228 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system, comprising:
an output;
a power source configured to provide a DC voltage to the output;
a pulsed source configured to provide a time-varying pulse train to the output;
a filter arranged between the pulsed source and the output; and
a sensing circuit configured to measure a time-varying voltage between the filter and the output, and based on the time-varying voltage, determine an unknown capacitance that the output is coupled to.

2. The system of claim 1, wherein a slope of the time-varying voltage is inversely proportional to the unknown capacitance.

3. The system of claim 1, wherein the sensing circuit is configured to measure a slope of the time-varying voltage and determine the unknown capacitance based on the slope of the time-varying voltage.

4. The system of claim 3, wherein the slope of the time-varying voltage is inversely proportional to the unknown capacitance.

5. The system of claim 1, based on the unknown capacitance, providing a control signal representative of an estimation of the unknown capacitance.

6. The system of claim 1, wherein the power source includes the pulsed source.

7. The system of claim 6, wherein the power source is a stepped source.

8. The system of claim 1, wherein the filter is a radio frequency filter.

9. The system of claim 1, wherein the unknown capacitance is part of an electrostatic chuck.

10. An apparatus, comprising:
a power source;
a first output configured for coupling to an unknown capacitance;
a square wave source configured to modify a second output of the power source;
a filter arranged between the square wave source and the first output; and
a voltage sensing circuit configured to measure a rate of change of a voltage between the filter and the first output and convert the rate of change to an approximation of the unknown capacitance.

11. The apparatus of claim 10, wherein the rate of change is inversely proportional to the unknown capacitance.

12. The apparatus of claim 10, wherein the apparatus is configured to power an electrostatic chuck.

13. The apparatus of claim 10, wherein the voltage sensing circuit comprises a comparator arranged across an impedance, the impedance coupled to a node between the filter and the first output.

14. The apparatus of claim 13, wherein one of two inputs to the comparator comprises a direct current bias.

15. The apparatus of claim 10, wherein the power source is configured to generate a stepped output.

16. A non-transitory, tangible computer-readable storage medium storing instructions that, when executed by a processor, cause a system to perform operations, comprising:
applying first power through a first filter to a first node;
applying second power through a second filter to a second node, wherein an unknown capacitance and a capacitance sensing circuit are arranged in parallel to each other and between the first and second nodes;
applying a time-varying signal, via the capacitance sensing circuit, through a loop including the first node, the second node, and the unknown capacitance; and
detecting a current in the capacitance sensing circuit and determining the unknown capacitance therefrom, wherein
the capacitance sensing circuit is floating.

17. The non-transitory, tangible computer-readable storage medium of claim 16, wherein the time-varying signal at the first node and the second node are phase shifted relative to each other.

18. The non-transitory, tangible computer-readable storage medium of claim 16, wherein the detecting is performed between a third filter and a fourth filter.

19. The non-transitory, tangible computer-readable storage medium of claim 18, wherein a current rate of change between the first node and the second node is proportional to the unknown capacitance.

20. The non-transitory, tangible computer-readable storage medium of claim 16, wherein the capacitance represents a clamping force of an electrostatic chuck on a substrate.
